(19) United States
(12) Patent Application Publication
(10) Pub. No.: US 2014/0218578 A1
(43) Pub. Date: Aug. 7, 2014

(54) CAMERA MODULE, SOLID-STATE IMAGING DEVICE, AND METHOD OF MANUFACTURING THE SAME

(71) Applicant: Kabushiki Kaisha Toshiba, Minato-Ku (JP)

(72) Inventor: Yusuke Kohyama, Oita (JP)

(73) Assignee: Kabushiki Kaisha Toshiba, Minato-Ku (JP)

(21) Appl. No.: 13/974,495

(22) Filed: Aug. 23, 2013

(30) Foreign Application Priority Data
Feb. 4, 2013 (JP) 2013-019713

(51) Int. Cl. H04N 5/3745; H01L 27/146

(52) U.S. Cl. CPC H04N 5/37457; H01L 27/14689
USPC 348/308; 438/60

(57) ABSTRACT

According to an embodiment of the present invention, a solid-state imaging device is provided. The solid-state imaging device includes a plurality of photoelectric conversion devices and an amplifier transistor. The plurality of photoelectric conversion devices photoelectrically converts an incident beam into signal charges. The amplifier transistor is provided on a face on the opposite side of the light incidence plane of the photoelectric conversion devices through an interlayer insulating film as the amplifier transistor is laid over the photoelectric conversion devices. The amplifier transistor has the area of a channel greater than the area of the incidence plane of a single photoelectric conversion device, and the amplifier transistor amplifies the signal charges.

### CROSS-REFERENCE TO RELATED APPLICATION

This application is based upon and claims the benefit of priority from Japanese Patent Application No. 2013-019713, filed on Feb. 4, 2013; the entire contents of which are incorporated herein by reference.

### FIELD

An embodiment described herein relate generally to a camera module, a solid-state imaging device, and a method of manufacturing the same.

### BACKGROUND

Heretofore, there is a backside illumination solid-state imaging device in which a plurality of transistors is provided on a face on the opposite side on which the beams of photoelectric conversion devices enter (in the following, referred to as “a front face”) for reading signal charges out of the photoelectric conversion devices or for amplifying the read signal charges, for example.

It is desired to realize a further reduction in the size and a higher image quality on such a backside illumination solid-state imaging device. However, in the case where the size of the photoelectric conversion device and the size of the transistor provided on the front face of the photoelectric conversion device are simply reduced, such a problem arises in that shot images are degraded.

### BRIEF DESCRIPTION OF THE DRAWINGS

FIG. 1 is a block diagram of the schematic configuration of a digital camera including a solid-state imaging device according to an embodiment;

FIG. 2 is an illustration of a CMOS sensor according to the embodiment when seen from the top face;

FIG. 3 is an illustration of an exemplary circuit configuration of a pixel unit according to the embodiment;

FIG. 4 is an illustration of the inside of the pixel unit and the inside of a logic unit according to the embodiment when seen from the cross section;

FIG. 5 is an illustration of the inside of the pixel unit according to the embodiment when seen from the top face;

FIGS. 6A to 9B are exemplary illustrations of the manufacturing process steps of the CMOS sensor according to the embodiment;

FIGS. 10A to 10C are illustrations of CMOS sensors according to a first exemplary modification to a third exemplary modification when seen from the cross section; and

FIG. 11 is an illustration of a CMOS sensor according to a fourth exemplary modification when seen from the top face.

### DETAILED DESCRIPTION

According to an embodiment of the present invention, a solid-state imaging device is provided. The solid-state imaging device includes a plurality of photoelectric conversion devices and an amplifier transistor. The plurality of photoelectric conversion devices photoelectrically converts an incident beam into signal charges. The amplifier transistor is provided on a face on the opposite side of the light incidence plane of the photoelectric conversion devices through an interlayer insulating film as the amplifier transistor is laid over the photoelectric conversion devices. The amplifier transistor has the area of a channel greater than the area of the incidence plane of a single photoelectric conversion device, and the amplifier transistor amplifies the signal charges.

In the following, a camera module, a solid-state imaging device, and a method of manufacturing the same according to an embodiment will be described in detail with reference to the accompanying drawings. It is noted that the present invention is not limited to the embodiment.

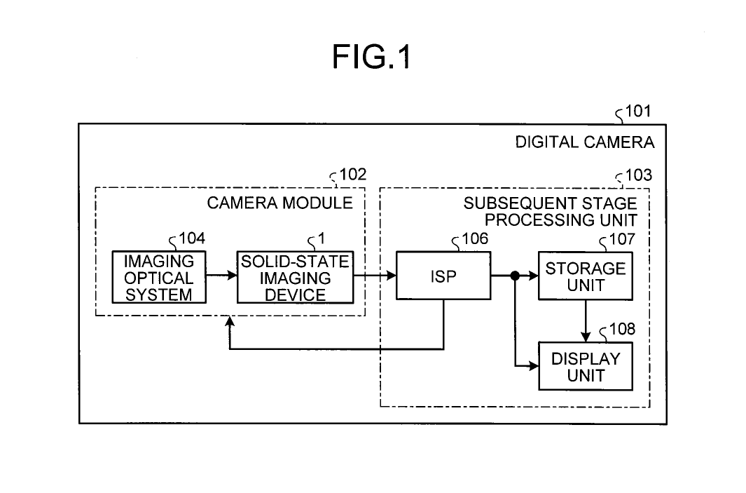

FIG. 1 is a block diagram of the schematic configuration of a digital camera 101 including a solid-state imaging device according to an embodiment. As illustrated in FIG. 1, the digital camera 101 includes a camera module 102 and a subsequent stage processing unit 103.

The camera module 102 includes an imaging optical system 104 and a solid-state imaging device 1. The imaging optical system 104 captures light from a subject, and forms a subject image. The solid-state imaging device 1 images the subject image formed by the imaging optical system 104, and outputs image signals obtained by imaging to the subsequent stage processing unit 103. The camera module 102 is applied to an electronic device such as a camera-equipped portable terminal other than the digital camera 101, for example.

The subsequent stage processing unit 3 includes an ISP (Image Signal Processor) 106, a storage unit 107, and a display unit 108. The ISP 106 signal-processes image signals inputted from the solid-state imaging device 1. The ISP 106 performs signal processing such as lens shading correction, spot correction, and noise reduction processing, for example. The ISP 106 then outputs image signals after signal-processed to the storage unit 107, the display unit 108, and the camera module 102. The image signals fed back from the ISP 106 to the camera module 102 are used to adjust and control the solid-state imaging device 1.

The storage unit 107 stores the image signals inputted from the ISP 106 as images. Moreover, the storage unit 107 outputs the image signals of the stored images to the display unit 108 in response to a user manipulation or the like. The display unit 108 displays images according to image signals inputted from the ISP 106 or the storage unit 107. The display unit 108 is a liquid crystal display, for example.

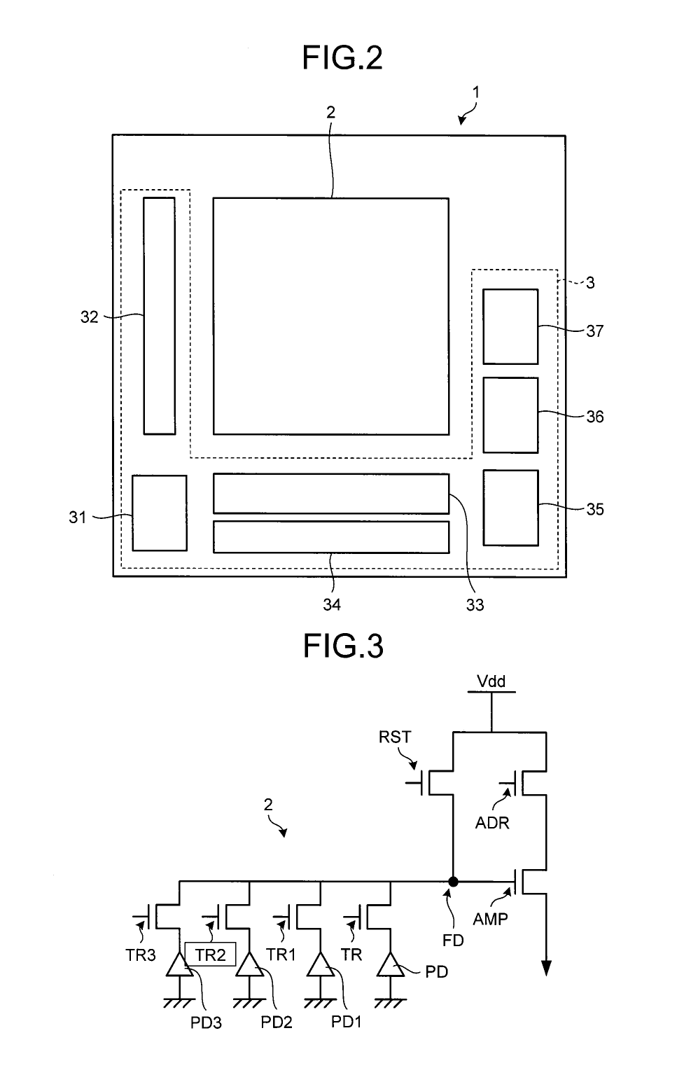

Next, the solid-state imaging device 1 included in the camera module 2 will be described with reference to FIG. 2. In the following, for an example of the solid-state imaging device 1, a so-called backside illumination CMOS (Complementary Metal Oxide Semiconductor) image sensor will be described as an example, in which an interconnection layer is formed on the face on the opposite side on which the incident beams of photoelectric conversion devices enter. The photoelectric conversion devices photoelectrically convert the incident beams.

FIG. 2 is an illustration of the solid-state imaging device 1 according to the embodiment (in the following, noted as “the CMOS sensor 1”) when seen from the top face. As illustrated in FIG. 2, the CMOS sensor 1 includes a pixel unit 2 and a logic unit 3.

The pixel unit 2 includes a plurality of photoelectric conversion devices arrayed in a matrix configuration. The photoelectric conversion devices photoelectrically convert the incident beams of a subject image formed by the imaging optical system 4 into an amount of signal charges (here, referred to as electrons) according to a quantity of light received (the intensity of light received) in a charge storage region. It is noted that an exemplary configuration of the pixel unit 2 will be described later with reference to FIGS. 3 to 5.

The logic unit 3 is disposed so as to surround the pixel unit 2. The logic unit 3 includes a timing generator 31, a vertical select circuit 32, a sampling circuit 33, a horizontal select circuit 34, an analog amplifier circuit 35, an A/D (analog to digital) converter circuit 36, a digital amplifier circuit 37, and the like.

The timing generator 31 is a processing unit that outputs pulse signals to be the criteria of operation timing to the pixel unit 2, the vertical select circuit 32, the sampling circuit 33, the horizontal select circuit 34, the analog amplifier circuit 35, the A/D converter circuit 36, the digital amplifier circuit 37, and the like.

The vertical select circuit 32 is a processing unit that in turn selects photoelectric conversion devices to read electric charges in units of rows out of the plurality of photoelectric conversion devices arrayed in a matrix configuration. The vertical select circuit 32 causes the photoelectric conversion devices to output, to the sampling circuit 33, the signal charges stored in the photoelectric conversion devices selected in units of rows as pixel signals that indicate the brightness of pixels.

The sampling circuit 33 is a processing unit that removes noise from the pixel signals inputted from the photoelectric conversion devices selected in units of rows at the vertical select circuit 32 by CDS (Correlated Double Sampling) and temporarily holds the pixel signals.

The horizontal select circuit 34 is a processing unit that in turn selects and reads the pixel signals held at the sampling circuit 33 for each row and outputs the pixel signals to the analog amplifier circuit 35. The analog amplifier circuit 35 is a processing unit that amplifies the analog pixel signals inputted from the horizontal select circuit 34 and outputs the analog pixel signals to the A/D converter circuit 36.

The A/D converter circuit 36 is a processing unit that converts the analog pixel signals inputted from the analog amplifier circuit 35 into digital pixel signals and outputs the digital pixel signals to the digital amplifier circuit 37. The digital amplifier circuit 37 is a processing unit that amplifies the digital signals inputted from the A/D converter circuit 36 and outputs the digital signals to a predetermined DSP (Digital Signal Processor, not illustrated).

As described above, in the CMOS sensor 1, the plurality of photoelectric conversion devices disposed on the pixel unit 2 photoelectrically converts incident beams into an amount of signal charges according to a quantity of light received and stores the signal charges. The logic unit 3 reads the electric charges stored in the photoelectric conversion devices as pixel signals for imaging.

Next, the circuit configuration and operation of the pixel unit 2 will be briefly described with reference to FIG. 3. FIG. 3 is an illustration of an exemplary circuit configuration of the pixel unit 2 according to the embodiment. It is noted that the circuit illustrated in FIG. 3 is a circuit that a unit corresponding to four pixels of a shot image is selectively extracted in the pixel unit 2.

As illustrated in FIG. 3, the pixel unit 2 includes photoelectric conversion devices PD, PD1, PD2, and PD3 and transfer transistors TR, TR1, TR2, and TR3. Moreover, the pixel unit 2 includes a floating diffusion FD, an amplifier transistor AMP, a reset transistor RST, and an address transistor ADR.

The photoelectric conversion devices PD, PD1, PD2, and PD3 are photodiodes whose cathodes are connected to a ground and whose anodes are connected to the sources of the transfer transistors TR, TR1, TR2, and TR3. The drains of the four transfer transistors TR, TR1, TR2, and TR3 are connected to a single floating diffusion FD.

When transfer signals are inputted to the gate electrodes of the transfer transistors TR, TR1, TR2, and TR3, the transfer transistors TR, TR1, TR2, and TR3 transfer signal charges photoelectrically converted at the photoelectric conversion devices PD, PD1, PD2, and PD3 to the floating diffusion FD. The source of the reset transistor RST is connected to the floating diffusion FD.

Moreover, the drain of the reset transistor RST is connected to a power supply voltage line Vdd. When a reset signal is inputted to the gate electrode of the reset transistor RST before transferring the signal charges to the floating diffusion FD, the potential of the floating diffusion FD is reset to the potential of the power supply voltage.

Furthermore, the gate electrode of the amplifier transistor AMP is connected to the floating diffusion FD. The source of the amplifier transistor AMP is connected to a signal line through which the signal charges are outputted to the logic unit 3, and the drain is connected to the source of the address transistor ADR. In addition, the drain of the address transistor ADR is connected to the power supply voltage line Vdd.

In the pixel unit 2, when an address signal is inputted to the gate electrode of the address transistor ADR, signals amplified according to the charge amount of signal charges being transferred to the floating diffusion FD are outputted from the amplifier transistor AMP to the logic unit 3.

As described above, in the pixel unit 2, the floating diffusion FD, the reset transistor RST, the address transistor ADR, and the amplifier transistor AMP are shared with the four photoelectric conversion devices PD, PD1, PD2, and PD3.

Thus, according to the pixel unit 2, the size can be reduced as compared with a pixel unit in which a floating diffusion, a reset transistor, an address transistor, and an amplifier transistor are provided for each photoelectric conversion device.

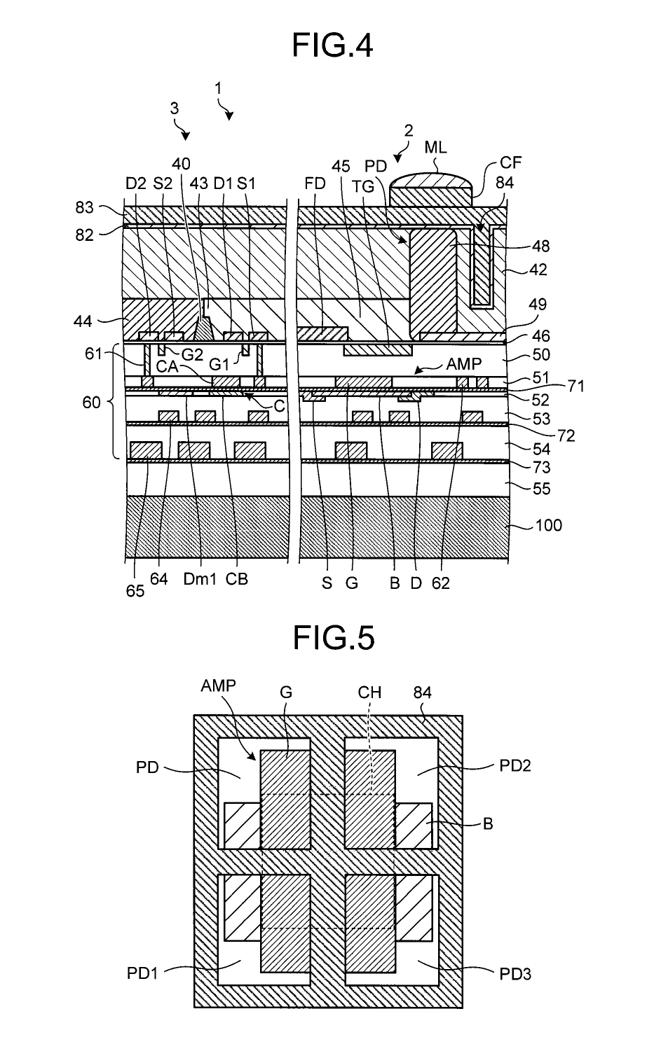

Next, the internal configurations of the pixel unit 2 and the logic unit 3 according to the embodiment will be described with reference to FIGS. 4 and 5. FIG. 4 is an illustration of the inside of the pixel unit 2 and the inside of the logic unit 3 according to the embodiment when seen from the cross section. FIG. 5 is an illustration of the inside of the pixel unit 2 according to the embodiment when seen from the top face.

Here, FIG. 4 schematically illustrates a unit corresponding to one pixel of a shot image in the pixel unit 2 and the cross section of a part of the logic unit 3. Moreover, in FIG. 5, for easily understanding the disposition and size of the amplifier transistor AMP, components other than the photoelectric conversion devices PD and PD1 to PD3, a device isolation region 84, and a gate electrode G, a body film B, and a channel CH of the amplifier transistor AMP are not illustrated in FIG. 5. Furthermore, the reset transistor RST and the address transistor ADR are not illustrated in FIGS. 4 and 5.

As illustrated in FIG. 4, the pixel unit 2 of the CMOS sensor 1 includes a micro lens ML, a color filter CF, the photoelectric conversion device PD, the floating diffusion FD, a multi-layer interconnection layer 60, and a support substrate 100 from the top layer to the bottom layer.

Moreover, in the logic unit 3, the active region and the like of the transistor of the logic circuit are provided on a layer the same as the layer on which the photoelectric conversion device PD, the floating diffusion FD, and so on are formed. Furthermore, the multi-layer interconnection layer 60 is provided on the layer below the layer on which the active region and the like are provided, and the support substrate 100 is provided on the layer below the multi-layer interconnection layer 60.

Here, the photoelectric conversion device PD is a photodiode formed of the PN junction of a P-type epitaxial layer 42 to an N-type charge storage region 48. The photoelectric conversion device PD photoelectrically converts a beam coming from the micro lens ML into signal charges, and stores the signal charges in the charge storage region 48.

It is noted that the photoelectric conversion device PD is electrically and optically isolated from the other photoelectric conversion devices by the device isolation region 84. As illustrated in FIG. 5, the device isolation region 84 is provided in grids when seen from the top face, for example. The photoelectric conversion devices PD, PD1, PD2, and PD3 are then provided in the inside of the grids.

Moreover, in the multi-layer interconnection layer 60 in the pixel unit 2, a gate electrode TG of a transfer transistor TR is provided on the upper layer side, and the amplifier transistor AMP is provided on the lower layer side of the gate electrode TG of the transfer transistor TR. The amplifier transistor AMP is a TFT (Thin Film Transistor) including the gate electrode G, the body film B, a source S, and a drain D.

As described above, since the amplifier transistor AMP is used for a TFT, the amplifier transistor AMP becomes a full depletion SOI (Silicon On Insulator) device. Therefore, the gain of the amplifier can be increased. The amplifier transistor AMP is provided on a face on the opposite side of the light incidence plane of the photoelectric conversion device PD through an interlayer insulating film, as the amplifier transistor AMP is laid over the photoelectric conversion device PD.

As described above, in the CMOS sensor 1, such a configuration is provided in which the photoelectric conversion device PD is stacked on the amplifier transistor AMP, which is not a configuration in which the photoelectric conversion device and the amplifier transistor are formed in the same layer.

Here, in a CMOS sensor in which a photoelectric conversion device and an amplifier transistor are formed in the same layer, in the case where the sizes of the photoelectric conversion device and the amplifier transistor are increased in order to improve image quality, the size of the pixel unit is increased. On the contrary, in the CMOS sensor 1, even though the sizes of the photoelectric conversion device PD and the amplifier transistor AMP are increased, the size of the pixel unit 2 is not increased so much as the CMOS sensor in which the photoelectric conversion device and the amplifier transistor are formed in the same layer.

Therefore, according to the CMOS sensor 1, the area occupied by the amplifier transistor AMP can be increased without increasing the size of the pixel unit 2 as compared with the CMOS sensor in which the photoelectric conversion device and the amplifier transistor are formed in the same layer. More specifically, the CMOS sensor 1 is provided with the amplifier transistor AMP having the area of the channel CH greater than the area of the light incidence plane of the photoelectric conversion device PD.

Thus, according to the CMOS sensor 1, 1/f noise can be decreased, which is increased inversely proportional to the area of the channel CH of the amplifier transistor AMP, and degradation in the image quality of a shot image caused by 1/f noise is suppressed, so that image quality can be improved.

Moreover, as illustrated in FIG. 5, the amplifier transistor AMP includes the body film B and the gate electrode G whose areas are greater than the area of the light receiving surface of the photoelectric conversion device PD when seen from the top face. The body film B and the gate electrode G are then disposed so as to extend over the four adjacent photoelectric conversion devices PD, PD1, PD2, and PD3 when seen from the top face. Thus, the amplifier transistor AMP including the channel CH extending over the four adjacent photoelectric conversion devices PD, PD1, PD2, and PD3 is implemented.

Moreover, as illustrated in FIG. 5, the gate electrode G of the amplifier transistor AMP is disposed on the lower layer side below the top face that is the light receiving surfaces of the photoelectric conversion devices PD, PD1, PD2, and PD3 when seen from the top face. Therefore, the material of the gate electrode G is a light reflection metal such as Cu (copper), for example, so that the gate electrode G also functions as a reflector for incident beams to the photoelectric conversion devices PD, PD1, PD2, and PD3.

Furthermore, the amplifier transistor AMP amplifies photoelectrically converted signal charges using the four photoelectric conversion devices PD, PD1, PD2, and PD3 over which the channel CH extends. As described above, in the CMOS sensor 1, since a single amplifier transistor AMP is provided for the four photoelectric conversion devices PD, PD1, PD2, and PD3, the area of the channel CH of the amplifier transistor AMP is greater than the area of the light receiving surface of the photoelectric conversion device PD as compared with the case where an amplifier transistor is provided for each photoelectric conversion device. Therefore, 1/f noise can be significantly reduced more than in a relatively small-sized amplifier transistor that is provided at a position laid over the device isolation region 84 when seen from the top face, for example.

However, the amplifier transistor AMP is provided on the pixel unit 2, and is not provided on the logic unit. For this reason, in the case where the amplifier transistor AMP is provided on the lower layer side of the photoelectric conversion device PD in the pixel unit 2, the thickness of the pixel unit 2 becomes thicker than the thickness of the logic unit 3, causing a possibility that the flatness of the overall CMOS sensor 1 might be impaired.

Therefore, in the CMOS sensor 1, for example, a dummy film Dm1 is provided on the logic unit 3, the dummy film Dm1 is formed of a material the same as a material of the component of the amplifier transistor AMP and formed on a plane the same as a plane of the component of the amplifier transistor AMP, and the film thickness of the dummy film Dm1 is the same as the film thickness of the component of the amplifier transistor AMP.

For example, as illustrated in FIG. 4, the dummy film Dm1 formed of a material the same as a material of the body film B of the amplifier transistor AMP and having the thickness equal to the thickness of the body film B is provided on the layer to be a plane the same as a plane of the body film B in the logic unit 3. Thus, it is possible to suppress the impairment of flatness as the overall CMOS sensor 1.

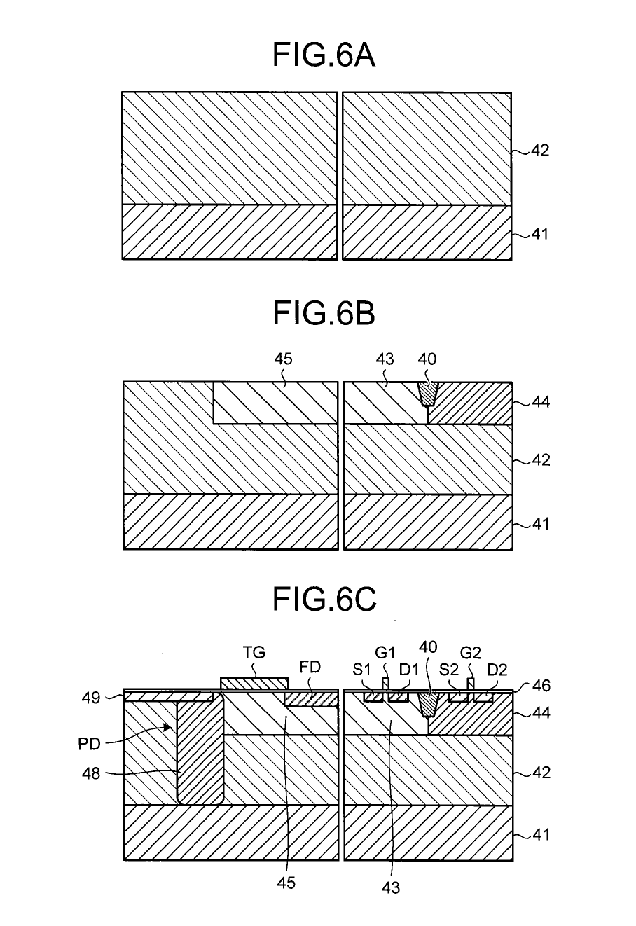

Next, a method of manufacturing the CMOS sensor 1 will be described with reference to FIGS. 6A to 9B. FIGS. 6A to 9B are illustrations of exemplary manufacturing process steps of the CMOS sensor 1 according to the embodiment.

In the case where the CMOS sensor 1 is manufactured, first, as illustrated in FIG. 6A, a P+ semiconductor substrate 41 is prepared, on the top face of which a P-type epitaxial layer 42 is formed. Here, the P+ semiconductor substrate 41 is an Si (silicon) wafer in which a P-type impurity such as boron is doped at a relatively high concentration, for example. Moreover, for example, the P-type epitaxial layer 42 is formed by epitaxially growing an Si layer while supplying a P-type impurity such as boron to the top face of the P+ semiconductor substrate 41.

After the formation, as illustrated in FIG. 6B, a P well 43 and an N well 44 for a logic circuit are formed at predetermined positions on a unit to be the logic unit 3 on the P-type epitaxial layer 42, and a P well 45 for a pixel is formed at a predetermined position on a unit to be the pixel unit 2.

Here, the P wells 43 and 45 are formed in which a P-type impurity such as boron is ion-implanted from predetermined positions on the top face of the P-type epitaxial layer 42 to the inside for annealing, for example. Moreover, the N well 44 is formed in which an N-type impurity such as phosphorus is ion-implanted from a predetermined position on the top face of the P-type epitaxial layer 42 to the inside for annealing, for example. Furthermore, a device isolation region STI (Shallow Trench Isolation) 40 is formed for an active device such as a transistor.

Subsequently, as illustrated in FIG. 6C, a gate insulating film 46 having SiO (silicon oxidize), for example, for a material is formed on the top face of the P-type epitaxial layer 42 on which the P wells 43 and 45 and the N well 44 are formed.

After the formation, the gate electrode TG of the transfer transistor TR is formed at a predetermined position on the P well 45 through the gate insulating film 46. Moreover, gate electrodes G1 and G2 for transistors to be provided on the logic unit 3 are formed at a predetermined position on the P well 43 and a predetermined position on the N well 44, respectively, through the gate insulating film 46. Here, the gate electrodes TG, G1, and G2 are formed of polysilicon, for example.

Subsequently, when seen from the top face, an N-type impurity is ion-implanted from both sides as sandwiching the gate electrode TG of the transfer transistor TR to the P well 45 for annealing, and the charge storage region 48 of the photoelectric conversion device PD and the floating diffusion FD are formed. It is noted that a shielding layer 49 is formed on the top face of the charge storage region 48 for preventing the leakage of stored signal charges.

Moreover, when seen from the top face, an N-type impurity is ion-implanted from both sides as sandwiching the gate electrode G1 to the P well 43 for annealing, and N-type diffusion regions S1 and D1 are formed. The N-type diffusion regions S1 and D1 become the source and the drain, respectively, of a transistor having the gate electrode G1 as the gate.

Furthermore, when seen from the top face, a P-type impurity is ion-implanted from both sides as sandwiching the gate electrode G2 to the N well 44 for annealing, and P-type diffusion regions S2 and D2 are formed. The P-type diffusion regions S2 and D2 become the source and the drain, respectively, of a transistor having the gate electrode G2 as the gate.

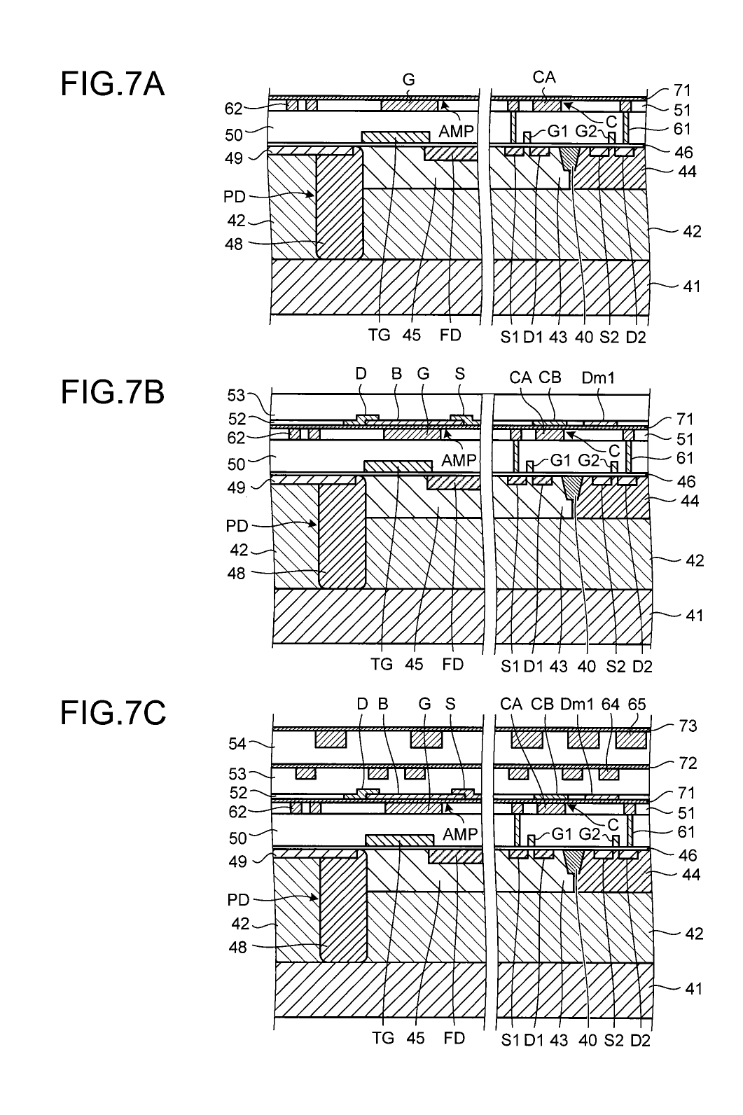

After the formation, as illustrated in FIG. 7A, an interlayer insulating film 50 having SiO, for example, for a material is formed on the gate electrodes TG, G1, and G2 and the gate insulating film 46. A through hole is formed which extends from the top face of the interlayer insulating film 50 to the top faces of the N-type diffusion region S1 and the P-type diffusion region D2, and then W (tungsten), for example, is filled in the through hole to form a contact hole 61.

In addition, an interlayer insulating film 51 is formed on the top face of the interlayer insulating film 50, and then a Cu interconnection 62 is formed in the interlayer insulating film 51 by damascene. At this time, the gate electrode G of the amplifier transistor AMP is simultaneously formed at a predetermined position of the interlayer insulating film 51 in the pixel unit 2, and a lower electrode CA for a capacitor C in the logic circuit is formed at a predetermined position of the interlayer insulating film 51 in the logic unit 3. Here, the gate electrode G is formed in such a way that the area when seen from the top face is greater than the area of the light incidence plane of a single photoelectric conversion device PD.

After the formation, an anti-diffusion film 71 that prevents the diffusion of CU is formed on the top faces of the Cu interconnection 62, the gate electrode G of the amplifier transistor AMP, the lower electrode CA of the capacitor C, and the interlayer insulating film 51. The anti-diffusion film 71 is an insulating film formed of SiN, for example. In the anti-diffusion film 71, the unit above the gate electrode G functions as a gate insulating film for the amplifier transistor AMP. Moreover, in the anti-diffusion film 71, a unit above the lower electrode CA of the capacitor C functions as an insulator for the capacitor C.

Subsequently, as illustrated in FIG. 7B, the body film B whose area is greater than the area of the light incidence plane of a single photoelectric conversion device PD when seen from the top face is formed on the gate electrode G through the anti-diffusion film 71. The body film B functions as a body for the amplifier transistor AMP, and is formed of an oxide semiconductor such as IGZO (Indium Gallium Zinc Oxidize), for example.

Moreover, in forming the body film B, the dummy film Dm1 having a film thickness the same as the film thickness of the body film B and formed of a material the same as the material of the body film B is simultaneously formed at a predetermined position on the anti-diffusion film 71 in the logic unit 3. After the formation, an interlayer insulating film 52 whose material is SiO, for example, is formed on the top faces of the body film B, the dummy film Dm1, and the anti-diffusion film 71.

Here, the body film B is formed for each pixel on the anti-diffusion film 71 in the pixel unit 2, and the dummy film Dm1 is formed on the anti-diffusion film 71 in the logic unit 3. Thus, it can be prevented that the flatness of the top face of the interlayer insulating film 52 is impaired as compared with the case where the dummy film Dm1 is not formed.

After the formation, predetermined positions on the interlayer insulating film 52 are selectively removed, and both end portions of the body film B and the anti-diffusion film 71 on the lower electrode CA of the capacitor C are exposed. The source S and the drain D of the amplifier transistor AMP are then formed on both end portions of the exposed body film B, and an upper electrode CB of the capacitor C is formed on the top face of the anti-diffusion film 71 on the exposed lower electrode CA of the capacitor C.

The source S, the drain D, and the upper electrode CB are simultaneously formed using a conductive member such as molybdenum, titanium nitride, tantalum nitride, and aluminum, for example. Thus, the amplifier transistor AMP is formed at a position laid over the photoelectric conversion device PD on a face on the opposite side (here, the top face) of the light incidence plane (here, the lower face) of the photoelectric conversion device PD through the interlayer insulating film 50.

Here, as described above, the area of the gate electrode G when seen from the top face and the area of the body film B provided on the gate electrode G through the anti-diffusion film 71 when seen from the top face are greater than the area of the light receiving surface of a single photoelectric conversion device PD. The channel CH of the amplifier transistor AMP then becomes a unit laid over the gate electrode G when seen from the top face of the body film B. Therefore, the area of the channel CH of the amplifier transistor AMP when seen from the top face is greater than the area of the light receiving surface of a single photoelectric conversion device PD.

As described above, in the CMOS sensor 1, such a configuration is provided in which the photoelectric conversion device PD is stacked on the amplifier transistor AMP. Thus, for example, as compared with a typical CMOS sensor in which an amplifier transistor is provided between adjacent photoelectric conversion devices, the area of the pixel unit 2 when seen from the top face can be reduced.

Moreover, according to the CMOS sensor 1, such a configuration is provided in which the photoelectric conversion device PD is stacked on the amplifier transistor AMP, so that the area of the channel CH of the amplifier transistor AMP can be increased. Therefore, according to the CMOS sensor 1, 1/f noise can be decreased, which is increased inversely proportional to the area of the channel CH of the amplifier transistor AMP, and degradation in the image quality of a shot image caused by 1/f noise can be suppressed, so that image quality can be improved.

Subsequently, an interlayer insulating film 53 is formed on the interlayer insulating film 52, the amplifier transistor AMP, and the capacitor C, and then the top face of the interlayer insulating film 53 is planarized by CMP (Chemical Mechanical Polishing), for example.

After the planarization, as illustrated in FIG. 7C, a Cu interconnection 64 is formed on the interlayer insulating film 53 by dual damascene, for example. An anti-diffusion film 72 is then formed on the top face of the interlayer insulating film 53. It is noted that the anti-diffusion films 71 and 72 are formed of the same insulating member. After the formation, the multi-layer interconnection layer 60 (see FIG. 4) is formed by repeating the formation of the interlayer insulating film 54, the Cu interconnection 65, and the anti-diffusion film 73 as necessary.

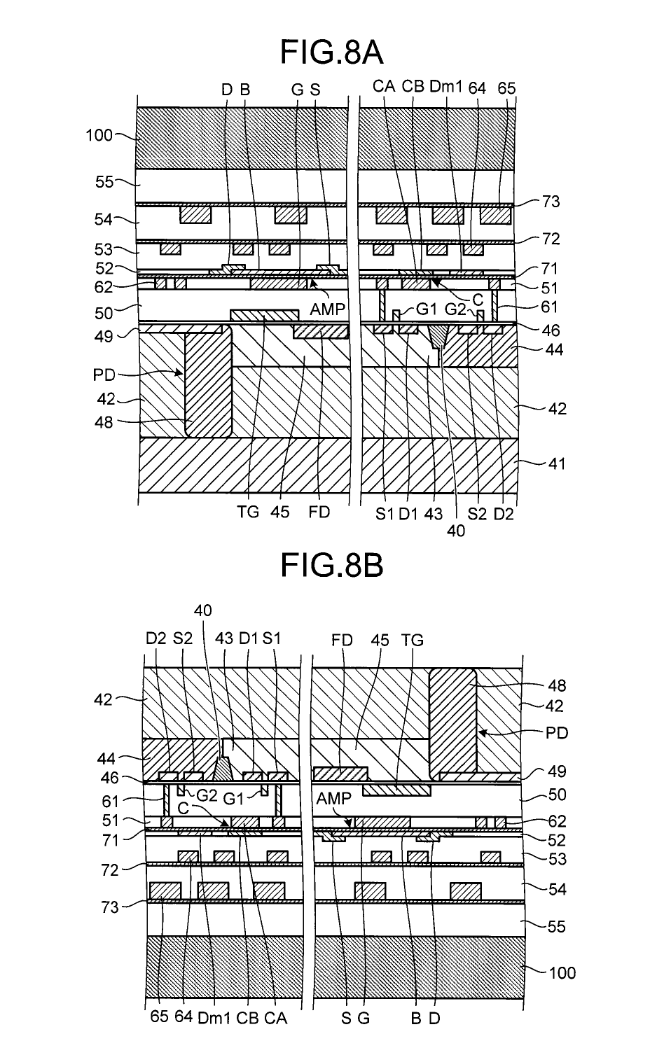

Subsequently, as illustrated in FIG. 8A, an interlayer insulating film 55 is formed on the top face of the anti-diffusion film 73, and then the support substrate 100 such as an Si wafer, for example, is bonded. After the bonding, as illustrated in FIG. 8B, the structure body having the support substrate 100 bonded is flipped, the semiconductor substrate 41 is ground by CMP, for example, and the P-type epitaxial layer 42 and the charge storage region 48 are exposed.

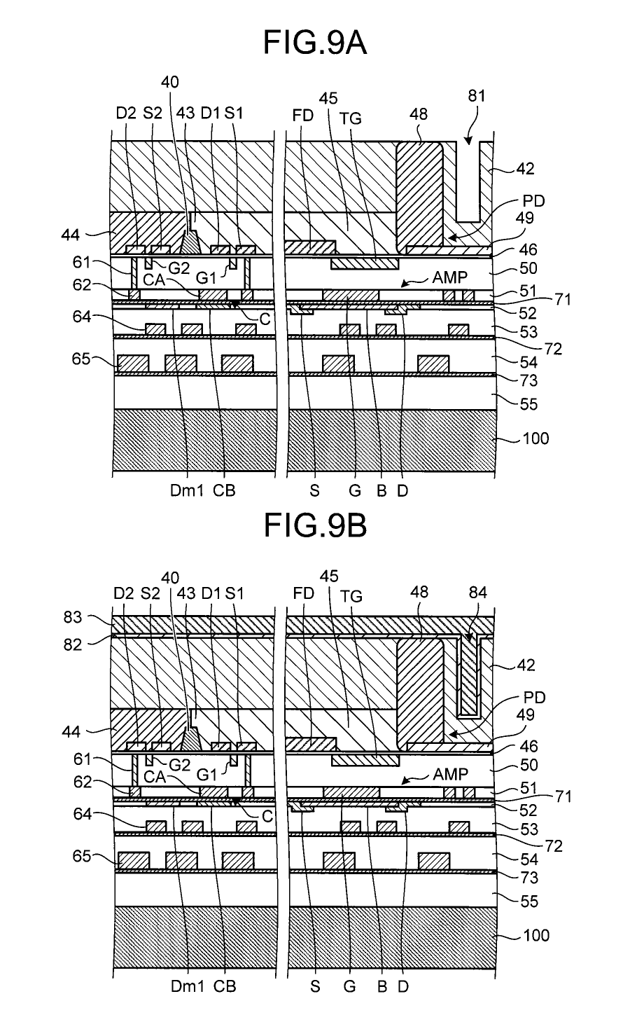

As illustrated in FIG. 9A, a DTI (Deep Trench Isolation) 81 is then formed between the pixels on the P-type epitaxial layer 42. Subsequently, as illustrated in FIG. 9B, a negative fixed electric charge film (not illustrated) and an anti-reflective film 82 are formed on the front faces of the exposed P-type epitaxial layer 42, the charge storage region 48, and the DTI 81.

After the formation, SiO, for example, is filled in the DTI 81, and the device isolation region 84 is formed. Moreover, a planarization film 83 having SiO, for example, for a material is formed on the top face of the anti-reflective film 82 on the P-type epitaxial layer 42 and the charge storage region 48.

Lastly, as illustrated in FIG. 4, the color filter CF and the micro lens ML are in turn stacked on the top face of the planarization film 83 on the charge storage region 48, so that the CMOS sensor 1 illustrated in FIG. 4 is manufactured.

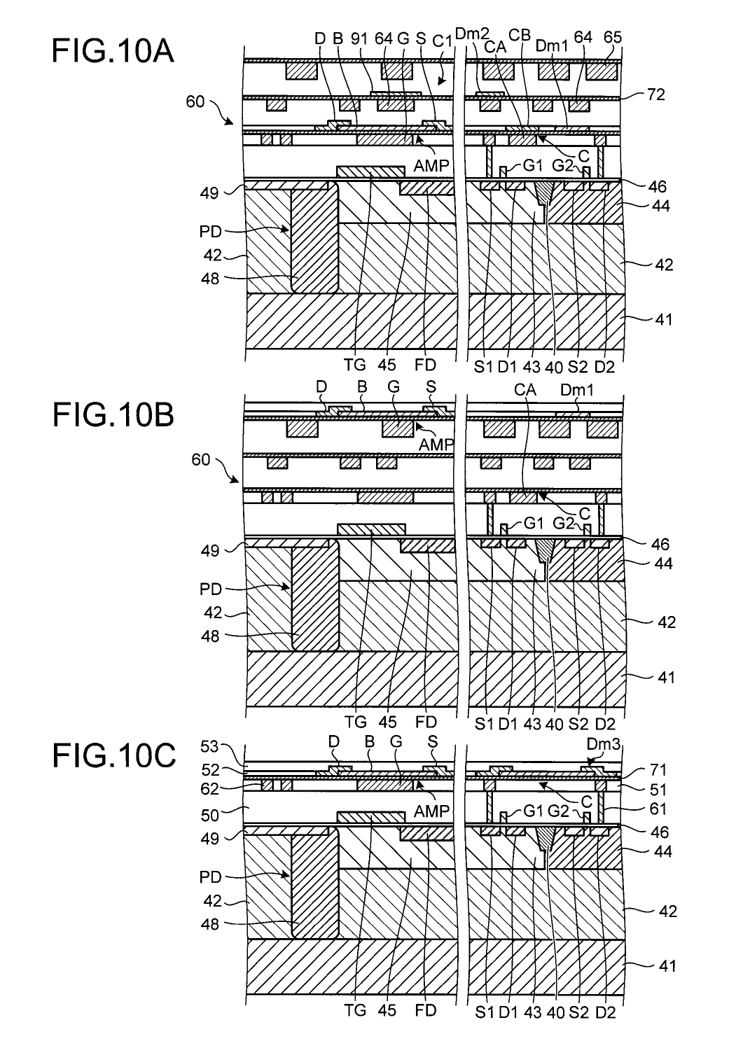

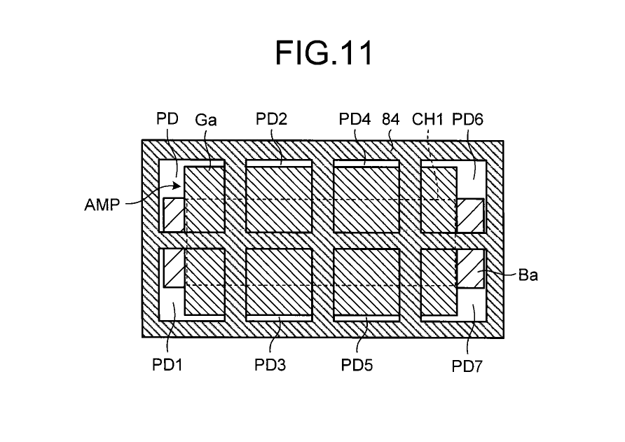

It is noted that the configuration of the CMOS sensor 1 described above is an example, and various modifications are possible. In the following, CMOS sensors according to exemplary modifications of the embodiment will be described with reference to FIGS. 10A to 11. FIGS. 10A to 10C are illustrations of CMOS sensors according to a first exemplary modification to a third exemplary modification when seen from the cross section. FIG. 11 is an illustration of a CMOS sensor according to a fourth exemplary modification when seen from the top face. It is noted that FIG. 10A to 10C partially illustrate a pixel unit and a logic unit in the stage prior to bonding a support substrate 100 (see FIG. 8).

Moreover, for easily understanding the disposition and size of an amplifier transistor and the like, components other than a photoelectric conversion device, a device isolation region, a gate electrode of an amplifier transistor, and a body film, a channel, and a gate electrode of a reset transistor are omitted in FIG. 11.

Furthermore, in the following description, the description of components having the similar functions as the components of the CMOS sensor 1 described with reference to FIGS. 2 to 9B is not repeated by designating the same reference numerals and signs as the reference numerals and signs illustrated in FIGS. 2 to 9B. In addition, here, for convenience, a description will be given as the P+ semiconductor substrate 41 side is the under layer and the multi-layer interconnection layer 60 side is the upper layer.

As illustrated in FIG. 10A, the CMOS sensor according to the first exemplary modification includes a capacitor C1 configured of a Cu interconnection 64, an anti-diffusion film 72, and an electrode film 91, and the capacitor C1 is provided on the upper layer side of an amplifier transistor AMP in a multi-layer interconnection layer 60. In the case where a global shutter function is provided on the CMOS sensor, for example, the capacitor C1 can be caused to function as an electric charge holding unit that temporarily holds photoelectrically converted signal charges. Moreover, in the case where a global shutter function is not provided, the capacitor C1 can also be caused to function as an electric charge holding unit that increases a total signal charge amount (a saturated charge amount) storable in pixels.

It is noted that in the case where the capacitor C1 is provided on a pixel unit 2, a dummy film Dm2 formed of a material the same as a material of the electrode film 91 and having a film thickness the same as the film thickness of the electrode film 91 is provided on a logic unit 3 on a layer the same as the layer on which the electrode film 91 of the capacitor C1 is formed. Thus, even though the capacitor C1 is provided, it is possible to suppress the impairment of the flatness of the overall CMOS sensor.

Furthermore, when such a configuration is provided in which the dummy film Dm2 is provided at a position opposite to the Cu interconnection through the anti-diffusion film 72, the capacitor can be formed of the dummy film Dm2, the anti-diffusion film 72, and the Cu interconnection. This capacitor can also be used for a logic circuit capacitor.

Moreover, as illustrated in FIG. 10B, the CMOS sensor according to the second exemplary modification includes an amplifier transistor AMP on the topmost layer of a multi-layer interconnection layer 60 in a pixel unit 2. Thus, external electrical contact can be easily made to a source S and a drain D of the amplifier transistor AMP in the later process steps. It is noted that also in the case of this configuration, a dummy film Dm1 is provided on a logic unit 3 on a layer the same layer of a body film B of the amplifier transistor AMP, so that it is possible to secure the flatness of the overall CMOS sensor.

Furthermore, as illustrated in FIG. 10C, a logic unit 3 of the CMOS sensor according to the third exemplary modification includes a dummy structure body Dm3 formed of a material the same as a material of an amplifier transistor AMP in the same shape on a layer the same layer of the amplifier transistor AMP stacked on a photoelectric conversion device PD in a pixel unit 2.

Of course, it is fine that a structure body is used for a transistor in the logic unit, not a dummy one. This means that a dummy one is disposed on a vacant region unnecessary for the circuit configuration. With this configuration, the thicknesses of the pixel unit 2 and the logic unit 3 can be made more uniform, so that it is possible to further improve the flatness of the overall CMOS sensor.

Moreover, as illustrated in FIG. 11, the CMOS sensor according to the fourth exemplary modification includes an amplifier transistor AMP that the areas of a body film Ba and a gate electrode Ga are increased so as to form a channel CH1 extending over eight adjacent photoelectric conversion devices PD and PD1 to PD7. With this configuration, the area of the channel CH1 of the amplifier transistor AMP is further increased, so that it is possible to further reduce 1/f noise.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A solid-state imaging device comprising:
a plurality of photoelectric conversion devices configured to photoelectrically convert an incident beam into signal charges; and
an amplifier transistor provided on a face on an opposite side of a light incidence plane of the photoelectric conversion devices through an interlayer insulating film as the amplifier transistor is laid over the photoelectric conversion devices, the amplifier transistor being configured to amplify the signal charges, the amplifier transistor having an area of a channel greater than an area of the incidence plane of one of the photoelectric conversion devices.

2. The solid-state imaging device according to claim 1, wherein:
the photoelectric conversion devices are arrayed in a matrix configuration as corresponding to pixels of a shot image; and
the amplifier transistor includes the channel extending over a plurality of the photoelectric conversion devices adjacent to each other, and amplifies signal charges photoelectrically converted by the plurality of the photoelectric conversion devices adjacent to each other.

3. The solid-state imaging device according to claim 1, further comprising a dummy film on a plane the same as a plane of a component of the amplifier transistor on a region other than a pixel region on which the plurality of photoelectric conversion devices is provided, the dummy film being formed of a material the same as a material of the component of the amplifier transistor and having a film thickness the same as a film thickness of the component of the amplifier transistor.

4. The solid-state imaging device according to claim 3, wherein a structure body formed of the dummy film has a shape the same as a shape of the amplifier transistor.

5. The solid-state imaging device according to claim 1, wherein the amplifier transistor is a TFT (Thin Film Transistor) including an oxidize film semiconductor for a body film.

6. The solid-state imaging device according to claim 1, further comprising a capacitor provided on the face on the opposite side of the light incidence plane of the photoelectric conversion devices through an interlayer insulating film as the amplifier transistor is laid over the photoelectric conversion devices, the capacitor being configured to temporarily hold signal charges to be photoelectrically converted by the photoelectric conversion devices.

7. The solid-state imaging device according to claim 1, wherein a gate electrode of the amplifier transistor is disposed at a position facing the face on the opposite side of the light incidence plane of the photoelectric conversion devices, the gate electrode being formed of a light reflection metal.

8. A camera module comprising:
an imaging optical system configured to capture light from a subject and form a subject image; and
a solid-state imaging device configured to image the subject image formed at the imaging optical system,
wherein the solid-state imaging device includes:
a plurality of photoelectric conversion devices configured to photoelectrically convert an incident beam into signal charges; and
an amplifier transistor provided on a face on an opposite side of a light incidence plane of the photoelectric conversion devices through an interlayer insulating film as the amplifier transistor is laid over the photoelectric conversion devices, the amplifier transistor being configured to amplify the signal charges, the amplifier transistor having an area of a channel greater than an area of the incidence plane of one of the photoelectric conversion devices.

9. A method of manufacturing a solid-state imaging device comprising:
forming a plurality of photoelectric conversion devices configured to photoelectrically convert an incident beam into signal charges; and
forming an amplifier transistor on a face on an opposite side of a light incidence plane of the photoelectric conversion devices through an interlayer insulating film as the amplifier transistor is laid over the photoelectric conversion devices, the amplifier transistor being configured to amplify the signal charges, the amplifier transistor having an area of a channel greater than an area of the incidence plane of one of the photoelectric conversion devices.

10. The method of manufacturing a solid-state imaging device according to claim 9, comprising forming a dummy film on a plane the same as a plane of a component of the amplifier transistor on a region other than a pixel region on which the plurality of photoelectric conversion devices is provided, the dummy film being formed of a material the same as a material of the component of the amplifier transistor and having a film thickness the same as a film thickness of the component of the amplifier transistor.

11. The method of manufacturing a solid-state imaging device according to claim 10, comprising forming a structure body on a region other than the pixel region, the structure body being formed of the dummy film in a shape the same as a shape of the amplifier transistor.

12. The method of manufacturing a solid-state imaging device according to claim 9, comprising forming, as the amplifier transistor, a TFT including an oxidize film semiconductor for a body film.

13. The method of manufacturing a solid-state imaging device according to claim 9, comprising forming a capacitor on the face on the opposite side of the light incidence plane of the photoelectric conversion devices through an interlayer insulating film as the amplifier transistor is laid over the photoelectric conversion devices, the capacitor being configured to temporarily hold signal charges to be photoelectrically converted by the photoelectric conversion devices.

14. The method of manufacturing a solid-state imaging device according to claim 9, comprising forming a gate electrode of the amplifier transistor at a position facing the face on the opposite side of the light incidence plane of the photoelectric conversion devices, the gate electrode being formed of a light reflection metal.

15. The method of manufacturing a solid-state imaging device according to claim 10, comprising forming an electrode of a capacitor on a region other than the pixel region, the electrode being formed of the dummy film.
